(19) United States
(12) Patent Application Publication
(10) Pub. No.: US 2014/0043902 A1
(43) Pub. Date: Feb. 13, 2014

(54) SEMICONDUCTOR STORAGE DEVICE

(71) Applicant: KABUSHIKI KAISHA TOSHIBA, Tokyo (JP)

(72) Inventor: Masaki UNNO, Kanagawa (JP)

(73) Assignee: Kabushiki Kaisha Toshiba, Tokyo (JP)

(21) Appl. No.: 13/783,367

(22) Filed: Mar. 3, 2013

(30) Foreign Application Priority Data
Aug. 10, 2012 (JP) 2012-178788

(51) Int. Cl. G11C 16/28

(52) U.S. Cl. CPC G11C 16/28
USPC 365/185.03; 365/185.21

(57) ABSTRACT

According to one embodiment, a storage unit with multiple memory cells that store data, and a bit-line switch circuit. The bit-line switch circuit is connected to a word line that is connected to the bit line, the source line, and the control gate of the memory cell, which is connected to both ends of the string, in order to write and to read out data from each memory cell. The bit-line wiring that is connected to the bit-line switch circuit is arrayed via a disconnection part into a high potential side wiring part including the bit-line wiring on the high potential side and a low potential side wiring part including the bit-line wiring on the low potential side. In the disconnection part is a dummy wiring part that is in a floating state.

### CROSS-REFERENCE TO RELATED APPLICATION

This application is based upon and claims the benefit of priority from Japanese Patent Application No. 2012-178788, filed Aug. 10, 2012; the entire contents of which are incorporated herein by reference.

### FIELD

Embodiments described herein relate a semiconductor storage device.

### BACKGROUND

In recent years, the demand for compact high-capacity information storage devices (memory storage devices) has grown rapidly. Especially, NAND-type flash memory and compact HDDs (Hard Disk Drives) have undergone rapid improvement in their storage densities, and have come to comprise a large share of the storage device market. Under these circumstances, several new memory devices with increased storage densities have also been proposed.

One such memory device that has been proposed to improve storage densities for information storage devices is a high-capacity memory BiCS (Bit Cost Scalable Memory), which is composed of an alternately-laminated electrode layer and interlayer dielectric layer, and a cylinder electrode that penetrates these layers.

### DESCRIPTION OF THE DRAWINGS

FIG. 1 is a plan view diagram showing schematically the array of the bit-line wiring part of the three-dimensional laminated-type semiconductor memory according to a first embodiment of the semiconductor storage device.

FIG. 2A is a close up diagram of the main parts of FIG. 1.

FIG. 2B is a cross-section diagram schematically showing the A-A cross-section of FIG. 2A.

FIG. 2C is a cross-section diagram schematically showing the B-B cross-section of FIG. 2A.

FIG. 2D is a cross-section diagram schematically showing the C-C cross-section of FIG. 2A.

FIG. 3A is an overview diagram of the semiconductor storage device of according to the first embodiment.

FIG. 3B is an overview illustrative diagram of two blocks of the semiconductor storage device according to the first embodiment.

FIG. 3C is an equivalent circuit schematic diagram of the semiconductor storage device according to the first embodiment.

FIG. 3D is an illustrative diagram showing the overview of the equivalent circuit of the bit-line switch circuit of the semiconductor storage device according to the first embodiment.

FIG. 4 is a bird's eye view of the semiconductor storage device (BiCS-NAND flash memory) according to the first embodiment.

FIG. 5A is a bird's eye view that extracts a part of the block (memory cell array) of the semiconductor storage device (BiCS-NAND flash memory) according to the first embodiment.

FIG. 5B is an equivalent circuit schematic diagram of one of the NAND cell units that are placed in the block (memory cell array) of the semiconductor storage device (BiCS-NAND flash memory) according to the first embodiment.

FIG. 6 is a plan view diagram schematically showing the array of the bit-line wiring part of the three-dimensional laminated-type semiconductor memory according to a second embodiment of the semiconductor storage device.

FIG. 7 depicts an expanded view of the array of the bit-line wiring part of the three-dimensional laminated-type semiconductor memory according to the second embodiment with dimensions.

FIG. 8 is a plan view diagram schematically showing the array of the bit-line wiring part of the three-dimensional laminated-type semiconductor memory according to a third embodiment of the semiconductor storage device.

FIG. 9 is a comparative diagram schematically showing the array of the bit-line wiring part of the third and the first embodiment.

FIG. 10 is a plan view diagram schematically showing the array of the bit-line wiring part of the three-dimensional laminated-type semiconductor memory that has been applied with the comparative example of the semiconductor storage device.

FIG. 11A is a close-up diagram of the main part of FIG. 10.

FIG. 11B is a cross-section diagram schematically showing the A-A cross-section of FIG. 11A.

FIG. 11C is a cross-section diagram schematically showing the B-B cross-section of FIG. 11A.

FIG. 11D is a cross-section diagram schematically showing the C-C cross-section of FIG. 11A.

### DETAILED DESCRIPTION

According to one embodiment, a semiconductor storage device is described in detail, with reference to the attached figures. These embodiments are examples which are not intended to limit the invention disclosed herein. Furthermore, in the figures shown below, there are cases where the depicted scales of the various elements are adjusted from reality to make the explanation clearer. The same is the case between each of the figures, and correspondence between depicted sizes in individual figures is not necessarily intended. Also, in both plan view diagrams and oblique perspective diagrams, there are cases where cross-hatchings are added to make the diagrams easier to comprehend.

The semiconductor storage device of this example embodiment includes a storage unit with multiple memory cells, bit-lines electrically connected to the memory cells, a voltage generating unit that generates a voltage to erase data in the memory cells, a sense amplifier that senses the data stored in the memory cells, and a bit-line switch circuit. The bit-line switch circuit has a first wiring part (R_{LV}), a second wiring part (R_{HV})e, a third wiring part (R_{D}) in an open state positioned between the first and second wiring parts, and a switching unit that switches the connection between the bit-lines, the voltage generating unit, and the sense amplifier.

Additionally, the first wiring part (R_{LV}) extends in a first direction, and the second wiring part (R_{HV}) is placed, with regard to the first wiring part, out of alignment in a second direction generally perpendicular to the first direction.

### Embodiment 1

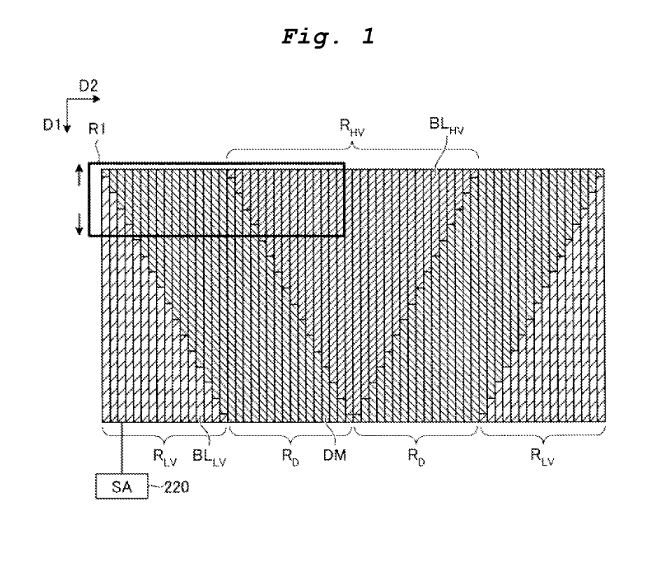

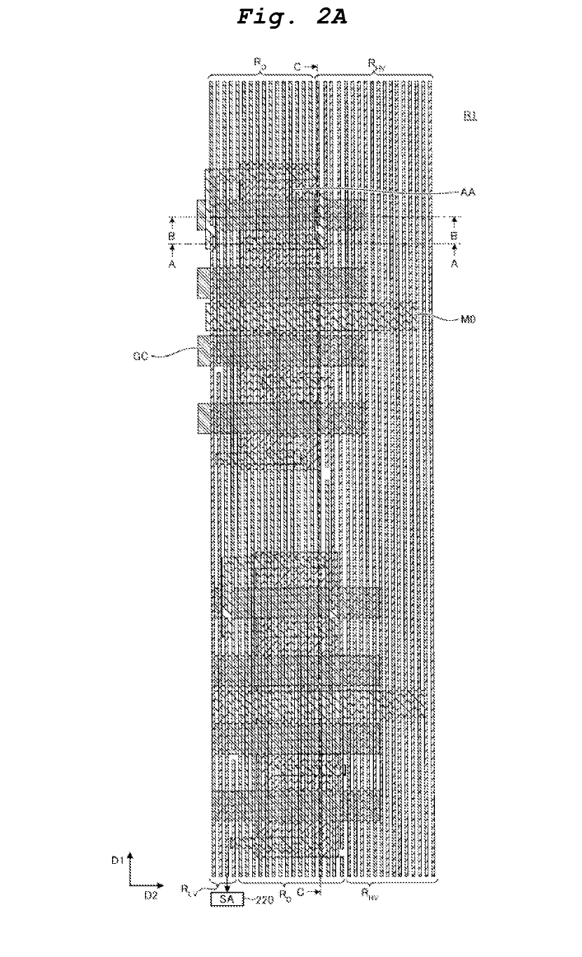

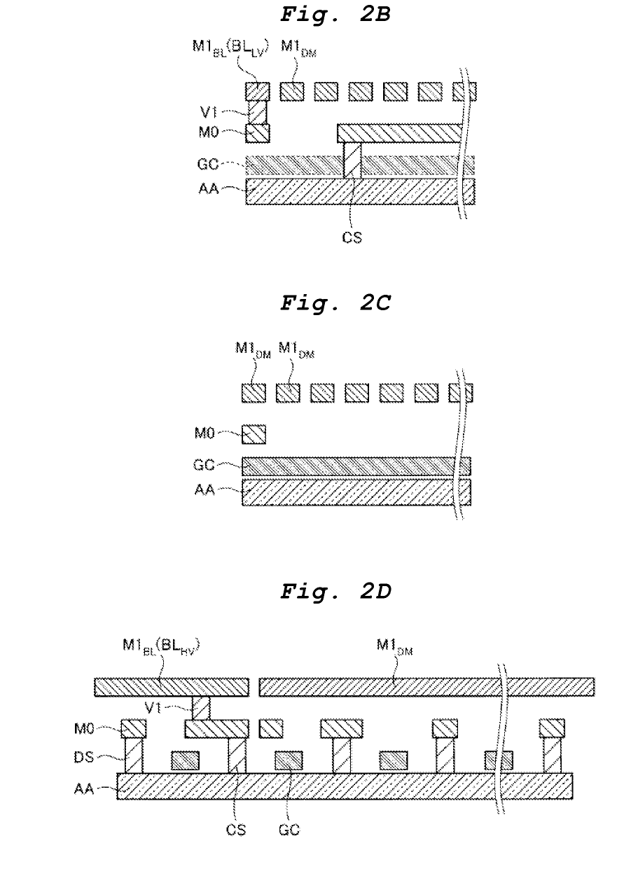

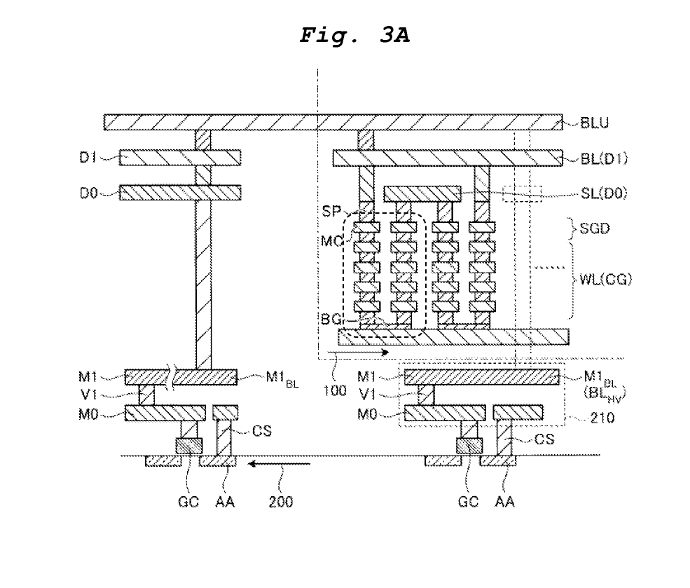

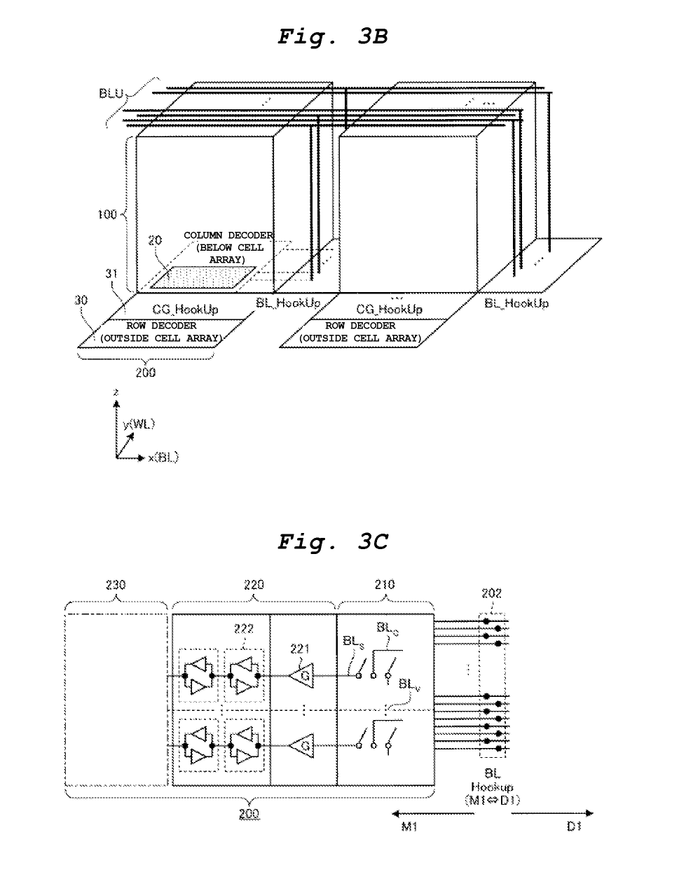

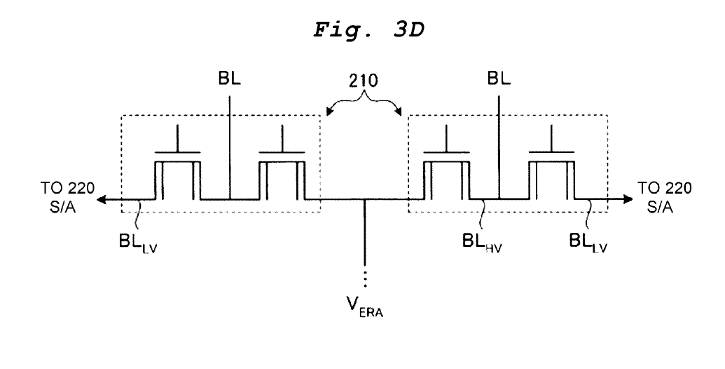

FIG. 1 is a plan view diagram schematically shows the array of the bit-line wiring part of the three-dimensional laminated type semiconductor memory that has been applied with the first embodiment of the semiconductor storage device. Laminated in this context means stacked and/or layered. FIG. 2A is a close-up diagram of the main parts of FIG. 1. FIG. 2B is a cross-section diagram schematically showing the A-A cross-section of FIG. 2A. FIG. 2C is a cross-section diagram schematically showing the B-B cross-section of FIG. 2A. FIG. 2D is a cross-section diagram schematically showing the C-C cross-section of FIG. 2A. FIG. 3A is an overview diagram of the semiconductor storage device of this embodiment. FIG. 3B is an overview illustrative diagram of two blocks of the semiconductor storage device of this embodiment. FIG. 3C is an equivalent circuit schematic diagram of the semiconductor storage device of this embodiment. FIG. 3D is an illustrative diagram showing the overview of the equivalent circuit of the bit-line switch circuit of the semiconductor storage device of this embodiment. It should be noted that, especially in FIG. 2A, it has been enlarged in the direction of the arrow in FIG. 1, and so in a real example the dimensional ratio of the length and breadth is different from that depicted. Furthermore, in the cross-section diagrams, insulating film such as interlayer dielectric films and gate insulating films are omitted so other components may be depicted clearly.

The semiconductor storage device of this embodiment is includes a storage unit 100, which comprises a three-dimensional laminated-type memory cell array, and a peripheral circuit unit 200, which, for example, is as a drive circuit supplying voltages for driving storage unit 100 (FIG. 3B). The semiconductor storage device of this embodiment minimizes the wiring necessary to connect the peripheral circuit units to the storage unit, such as the bit-line wiring associated with bit-line switch circuit 210 (FIG. 3C).

The memory cell array of storage unit 100 is composed of BiCS memory. Storing data to and reading data from this cell array is conducted by the peripheral circuit unit 200, which includes the bit-line switch circuit 210. In a three-dimensional laminated-type memory cell, memory cells are linked up to compose a memory string SP. Therefore, voltage cannot be directly applied to the channel of the string SP. To address this, a method using GIDL (Gate Induced Drain Leakage) is employed, which takes out the charge current to the drain side and thereby erasing stored data. By applying high potential to the source line that is connected to the source domain or to the bit-line, induced potential is generated in the channel formed under the gate electrode, GC, and by taking out the charge current to the drain side, the data are erased. On the other hand, regarding the read out of data, the bit-line is connected to the sense amplifier, and a low potential is applied.

In this way, when using a three-dimensional laminated-type memory cell structure, it is necessary to apply two types of potential—high potential and low potential—for erasing and reading out data. Embodiments of the present disclosure possess a wiring structure in the wiring part (bit-line wiring part R1) which applies these two types of potential to the storage unit 100.

As shown in FIG. 1, the bit-line wiring part R1 includes a first wiring part (R_{LV}) with wires which extend in the first direction (D1 in FIG. 1), a second wiring part (R_{HV}), which offset with respect to the first wiring part in the second direction (D2 in FIG. 1) with wires also extending in the first direction, and a third wiring part (R_{D}) that is placed in the offset region between the first wiring part and the second wiring part. The third wiring part is in an open state (i.e., is not electrically connected). The wires of the third wiring part also generally extend in the first direction.

The first wiring part (R_{LV}) is connected to the bit-lines and to the sense amplifier 220. The connection between the bit-line and the first wiring part and the second wiring part can be switched by the bit-line switch circuit 210.

The first wiring part (R_{LV}) will be called the low potential side wiring part, R_{LV}, and the second wiring part (R_{HV}) will be called the high potential side wiring part, R_{HV}. The third wiring part (R_{D}) will be called the dummy wiring part, R_{D}.

The power supply circuit 230 generates voltage that is used for the erasing of the memory cells. The sense amplifier 220 senses the data (stored as electrical charges) in the memory cell. The bit-line switch circuit 210, while not shown in FIG. 1 and FIG. 2A, is disposed in a lower layer than these bit-line wiring parts R1 (wiring parts R_{LV}, R_{HV}, R_{D}).

The peripheral circuit unit 200 has a bit-line wiring part R1, which is connected to the bit-line BL (D1), via the bit-line switch circuit 210. As shown in FIG. 1 and FIG. 2A, the bit-line wiring part R1 is divided into the low potential side wiring part, R_{LV}, that connects to the sense amplifier 220 and the high potential side wiring part, R_{HV}, that applies erasing voltage to the memory cell, MC. The dummy wiring part, R_{D}, which is in an open state, is placed in between them as a divider part which ensures there is a space between the low potential side wiring part, R_{LV}, and the high potential side wiring part, R_{HV}. The column decoder places the same basic circuitry along the word line direction.

Furthermore, the bit-lines, as shown in FIG. 1 and FIG. 2A, are out of alignment at a constant width offset in the second direction D2 via the dummy wiring part R_{D}, which has a set width.

The size of this offset width (misalignment width) can be seen from the misalignment/offset in the positions of the low potential side wiring part R_{LV}, the high potential side wiring part R_{HV}, and the dummy wiring part R_{D}, on the top edge and the bottom edge of FIG. 1 and FIG. 2A. When the wirings of the top edge and the bottom edge are compared, it is clear that in this example embodiment, the wiring parts R_{LV} and R_{HV} are out of alignment by four wires.

AA, depicted in FIG. 2A, is the active layer (active area) and is formed in a rectangular area on the surface of the semiconductor substrate. A gate electrode wiring GC is formed on top of the active layer over a gate insulating film that is not shown in the diagram. That is, the bit-line wiring is positioned so that it is offset in direction D2 at a constant width via the dummy wiring part R_{D}. For this reason, in effect, the ends of the wires of the low potential side wiring part R_{LV} and the M1-side wiring part R_{HV}, which is the high-voltage topmost layer wiring, are separated by the same amount as the offset/misalignment width. The breakdown voltage will increase according to the offset distance.

That is, the first and the second wiring parts (low potential side wiring part, R_{LV}, high potential side wiring part, R_{HV}) are, as shown in FIG. 1 and FIG. 2A, separated via a dummy wiring part that is diagonally formed so that it is at a set angle to the first direction D1, and so that the end parts are along parallel lines. These first and second wiring parts are also out of alignment in the second direction D2 which is in a perpendicular direction to the first direction by four wires. Moreover, in this misalignment (offset) domain, the first and the second wiring parts are separated via the divider part that is diagonally shaped so that the divider part is at a set angle to the first direction. In this way, the divider part is out of alignment in the second direction, which is a direction perpendicular to the first direction, and the third wiring part is arrayed in this misalignment (offset) domain.

Therefore, it is possible to heighten the operating voltage without greatly increasing the occupied area necessary for wiring.

Furthermore, as shown in FIG. 2B and FIG. 2D, the first layer wiring, M0, and the second layer wiring, M1, are sequentially laminated in this upper layer, and this second layer wiring, M1, composes the bit-line wiring part R1. M1, which is the topmost layer wiring shown in the diagram is the second layer wiring that is located on the upper layer side, and composes the bit-line wiring (BL_{LV}, BL_{HV}, and dummy wiring M1_{DM}). This bit-line wiring part, R1, is positioned in the lower layer part of the memory cell, MC, which composes the storage unit 100. The bit-line wiring part (low potential side wiring part, R_{LV}, and high potential side wiring part, R_{HV}) R1 is connected to the first layer wiring, M0, via the Via V1, and is electrically connected to the source domain that is formed in the active layer, AA, via the source contact, CS. On the other hand, the drain domain that is formed in the active layer, AA, is connected to the select gate line (not shown in the diagram) via the drain contact, DS, and the first layer wiring, M0.

Overview illustrative diagrams of the semiconductor storage device of this embodiment are shown in FIG. 3A and FIG. 3B. The semiconductor storage device of this embodiment includes a storage unit 100 and a peripheral circuit unit 200. The storage unit 100 is installed in the semiconductor substrate, and includes a plurality of strings SP, that series-connects (serially connects) multiple memory cells that store data and selection transistors at each end of the serially connected memory cells. The peripheral circuit unit 200 controls the bit-line and the source line that are connected to both ends of the string, SP, in order to write to and to read out data from each memory cell, MC, of the storage unit 100, and the word line that is connected to the control gate of the memory cell MC. The bit-line switch circuit 210 of the peripheral circuit unit 200 is connected to the high potential side wiring part, R_{HV}, that applies erasing voltage to the memory cell. The bit-line switch circuit 210 is also connected to the low potential side wiring part, R_{LV}, which is connected to the low potential side that is connected to the sense amplifier, and the bit-line switch circuit 210 switches between these two wiring parts.

In the upper layer, an upper-level bit-line BLU, which is an upper level wiring of the bit-line that is connected to the bit-line wiring, is equipped with a column decoder 20 in the lower layer of the memory cell array. On the outside of the column decoder 20, which is immediately below the cell array, a row decoder 30 is connected via a control gate connector part (CG_Hook Up) 31.

Of the peripheral circuit unit 200, the bit-line wiring M1_{BL} that is connected to the bit-line switch circuit 210, is connected to the bit-line BL (D1). This bit-line BL (D1) is connected to the cell array via the upper level bit-line, BLU, which is the upper level wiring. The writing and read out of data are conducted by, with regard to the string SP, switching the connection of the bit-line wiring that is on the low potential side BL_{LV} (low potential side wiring part R_{LV}) and the bit-line wiring that is on the high potential side BL_{HV} (high potential side wiring part R_{HV}). The bit-line wiring, BL_{LV}, on the low potential side composes the first wiring part, and the bit-line wiring, BL_{HV}, on the high potential side composes the second wiring part. The string, SP, is composed of laminate structures of the memory cell, MC. As depicted in FIG. 3A, the bases of two laminate memory cell structures are connected by a back gate, BG, and form a U-shaped memory cell string, SP. The bit-line switch circuit 210 is equipped with switching transistors, such as FET which has the active layer, AA, as the source drain, and is connected to the second layer wiring, M1 (bit-line wiring) via the Via, V1, in regards to the first layer wiring, M0.

Also, as shown in FIG. 3C, the peripheral circuit unit 200 possesses a bit-line switch circuit 210, a sense amplifier 220, and a power supply circuit 230. 202 is a bit-line connector unit, and is the connector unit for the bit-line wiring part, R1, that runs on top of the storage unit 100 and the peripheral circuit unit 200, and is connected to the topmost layer wiring, M1, via the Via, V1. The bit-line switch circuit 210 is composed so that it can switch the portion of the bit line wiring, bit-line BL_{C}, which is connected to each cell array, to the bit-line wiring BL_{S} (BL_{LV}) which is connected to the sense amplifier 220 and the bit-line wiring BL_{S} (BL_{HV}) which is connected to the high potential line (not shown in the diagram) and which becomes the erasing voltage.

Furthermore, the sense amplifier 220 is composed of an amplifier circuit 221 and a latch circuit 222 which is made of a flip-flop, and is composed so that each piece of data that is amplified by the amplifier circuit 221 can be temporarily saved in the flip-flop. The sense amplifier 220 is arranged on the underside of the memory cell array.

As the overview of the equivalent circuit schematic of the bit-line switch circuit 210 is shown in FIG. 3D, the bit-line switch circuit 210 each possesses two transistors. With these two transistors, the bit-line, BL, is connected to the low potential side bit-line wiring, BL_{LV}, or the high potential side bit-line wiring, BL_{HV}. The low potential side bit-line wiring, BL_{LV}, that is connected to the sense amplifier 220 and the high potential side bit-line wiring, BL_{HV}, that is connected to the high potential line, V_{ERA}, which becomes the erasing voltage, are adjacent to each other. This high potential line, V_{ERA}, is connected to the power supply circuit (voltage generating unit) 230. At the time of erasing, at the bit-line switch circuit 210 in FIG. 3D, the inner transistor turns on, and the bit-line, BL, is connected to the high potential line, V_{ERA}. In this example, when reading out and writing data, the inner transistor turns off, the outer transistor turns on, and the bit-line, BL, is connected to the low potential side bit-line wiring, BL_{LV}, via the high potential side bit-line wiring, BL_{HV}, and the bit-line, BL, will be connected to the sense amplifier 220.

Next, the operating voltage of this semiconductor storage device and the placement of the dummy wiring part will be discussed. When the voltage per unit of distance between adjacent wires is Vₒ, the width, d, between one bit-line wiring at the dummy wiring part, R_{D}, which is the dividing part, should be formed to satisfy the equation below. Here the width, d, shall be the distance from the center of one wiring to the center of another wiring.

ΔV/(n+1)≦d·V₀

ΔV is the maximum potential difference between the high potential side wiring part and the low potential side wiring part.

Here, n is the number of wiring pairs of the bit-line wiring that is composed of the high potential wiring and the low potential wiring. Therefore, the width of the dummy wiring part, which is the divider part R_{D}, will be (n+1)·d. For example, if the potential difference between the high potential side wiring and the low potential side wiring is 20 V and the voltage between the wirings at a set spacing is 5V, one would need to add just n=3 dummy lines.

Also note, the wiring of the bit-line wiring part that is made of the low potential side wiring part, R_{LV}, and the high potential side wiring part, R_{HV}, and the wiring of the dummy wiring part, R_{D}, are generally the same width, which simplifies the layout of the wiring and improves the precision of lithography.

The domain between the low potential side wiring part R_{LV} and the high potential side wiring part R_{HV} is completely divided, and a dummy line that is in a floating state is positioned between with the same line width/space as the high and low potential side wiring parts. With this arrangement it is possible to solve the voltage problem during erasing. For example, in the case of there being four dummy lines, due to the inter-wiring capacitance it will become charged isoelectrically, but the inter-wiring potential difference will be around 5V, and so there will be no voltage problem. Similarly, the contact between adjacent wiring problem can be solved.

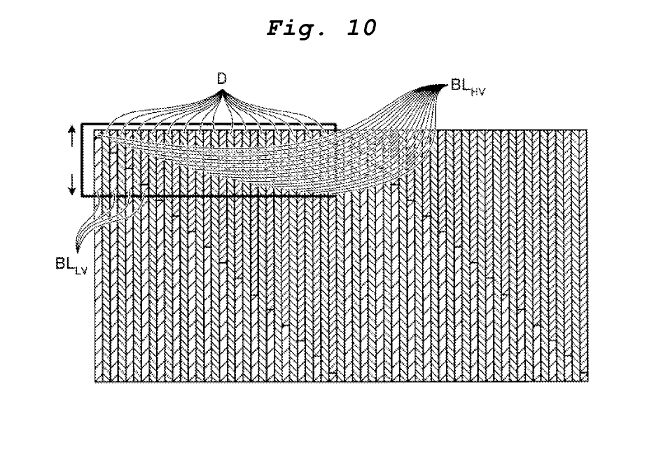

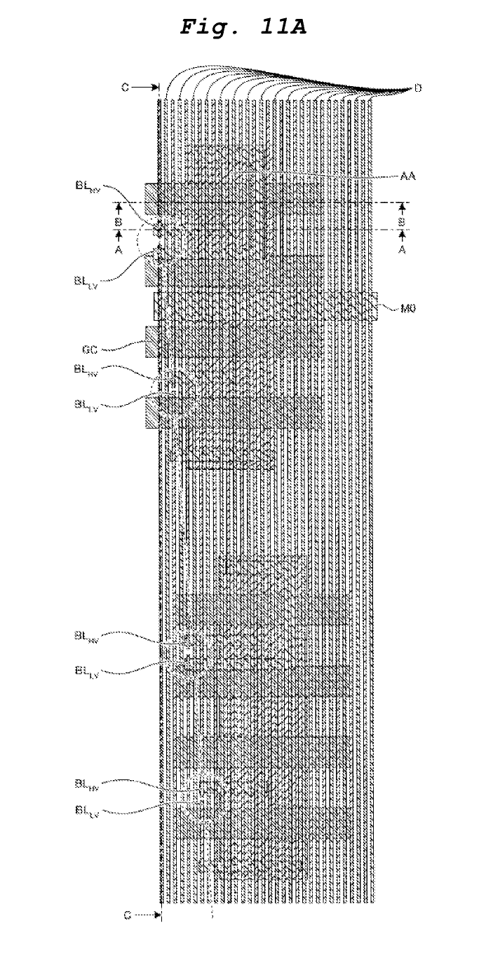

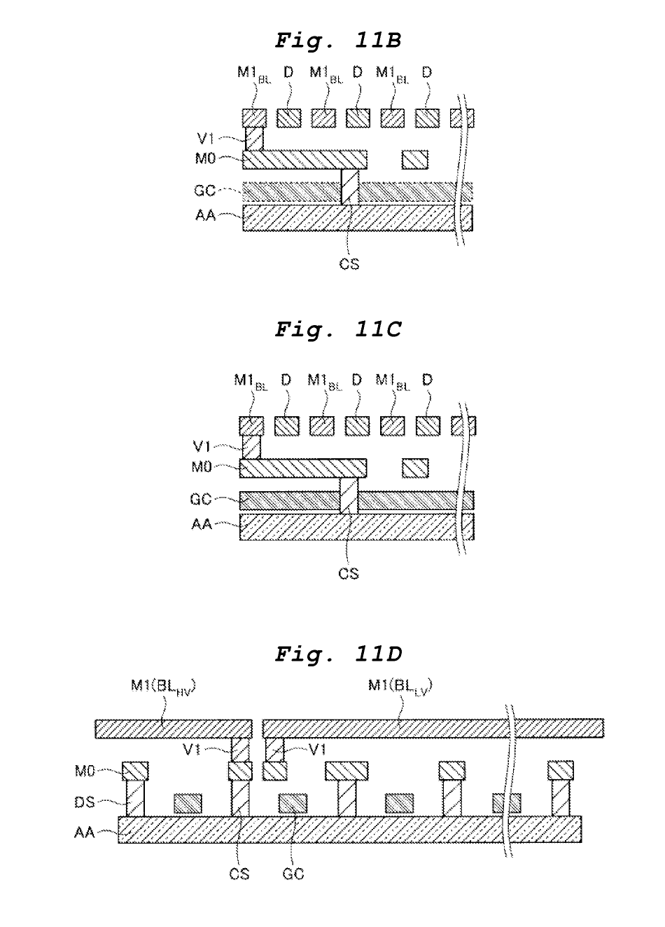

In regards to this, as a comparison, the bit-line wiring of the comparative example and a detailed layout and an overview diagram of the dummy line are each shown in FIG. 10 and FIGS. 11A to 11D. FIG. 10 is a plan view diagram schematically showing the array of the wiring of the bit-line wiring part of the three-dimensional laminated-type semiconductor memory that has been applied with the comparative example of the semiconductor storage device. FIG. 11A is a close-up of the main part of FIG. 10, FIG. 11B is a cross-section diagram schematically showing the A-A cross-section of FIG. 11A. FIG. 11C is a cross-section diagram schematically showing the B-B cross-section of FIG. 11A. FIG. 11D is a cross-section diagram schematically showing the C-C cross-section of FIG. 11A. FIG. 1 and FIGS. 2A to 2D which show the three-dimensional laminated-type semiconductor memory of this embodiment correspond to this FIG. 10 and FIGS. 11A to 11D. In the comparative example, it has a structure that adds one dummy line, D, between the bit-line wiring on the low voltage side, BL_{LV}, that is connected to the sense amplifier (SA: not shown in the diagram) and the bit-line wiring on the high voltage side, BL_{HV}, which is there to apply the erasing voltage to the cell. However, there is a drawback with this structure; voltage cannot be maintained because a large voltage difference (for example over 20 V) will arise between the bit-line wiring, BL_{HV}, which includes the dummy line, D, and BL_{LV}. FIG. 11D is a diagram that shows the neighborhood of the domain that is enclosed by the dotted line in FIG. 11A, and there are places where the bit-line wiring BL_{HV} and BL_{LV} are adjacent.

Also, even regarding the Via, V1, on the bit-line wiring that is positioned in order to connect to the upper layer or the lower layer, a similar voltage problem arises. For example, the Via, V1, on the bit-line wiring BL_{LV}, that is positioned in order to connect to the lower layer as shown in FIG. 11D, is adjacent to a Via V1 that is below the bit-line wiring BL_{HV} on the high potential side. Additionally, the fact that there is a limit to the disconnection of the dummy line itself, caused by the disconnection points of the bit-line wiring that adjoin the dummy line, D, is also problematic.

As described above, the semiconductor storage device that pertains to this embodiment completely divides the bit-line wiring on the high potential side BL_{HV} and the bit-line wiring on the low potential side BL_{LV}. This embodiment positions a dummy line DM that is in a floating state in the dummy wiring part R_{D}, which composes the divider part that is placed in between them, at the same width/space pattern as the other wiring parts. Due to this, it is possible to solve the voltage problem which arises during erasing due to the high required voltages. The effects of this embodiment are also clear from comparisons between FIG. 1, FIG. 2A through FIGS. 2 to 4 and FIG. 10, FIG. 11A through FIG. 11D. For example, in the case that 16 dummy lines are put inside, as in this embodiment, when a voltage of 20 V is applied at the time of erasing, it is charged to the potential difference by the capacitance of the inter-wire; however, the inter-wire potential difference will be around 1.25 V, so it is an outstanding composition in terms of voltage.

The contact between adjacent wiring problem can be solved similarly. In the case of inserting 4 dummy lines, when 20 V are applied during erase, due to the inter-wiring capacitance, it will become charged isoelectrically, however, the inter-wiring potential difference will be around 5V, and so there will be no voltage problem. Similarly, the contact between adjacent wiring problem can be solved.

Furthermore, in the three-dimensional laminated-type semiconductor memory that pertains to this embodiment, the bit-line wiring is mirrored and arranged so that they form a symmetric structure. This is not necessary, but in the case of not mirroring it, the boundaries where the bit-line wiring on the high potential side BL_{HV} and the bit-line wiring on the low potential side BL_{LV} are in contact will increase. As a result, there is the inconvenience of a necessity to insert more dummy lines, DM. Hence, for efficiency, the bit-line wiring part should be mirrored.

Next, the composition of the storage unit 100 which is made of BiCS memory and which composes the three-dimensional laminated-type semiconductor memory that pertains to the embodiment of this invention will be described. The embodiment of this invention is not limited by following configuration. A memory cell array formation may be disclosed in U.S. patent application Ser. No. 12/532,030. U.S. patent application Ser. No. 12/532,030, the entire contents of which are incorporated by reference herein.

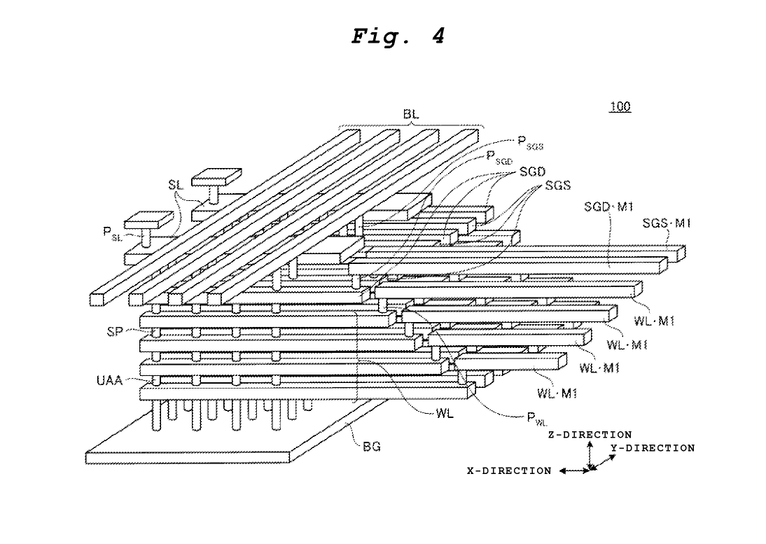

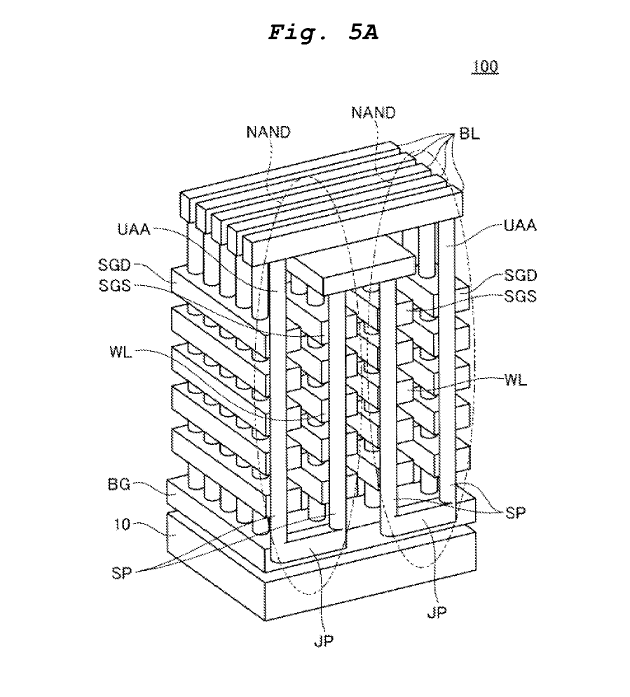

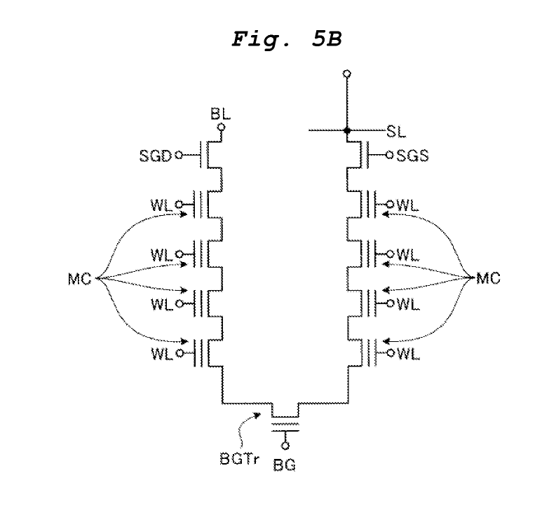

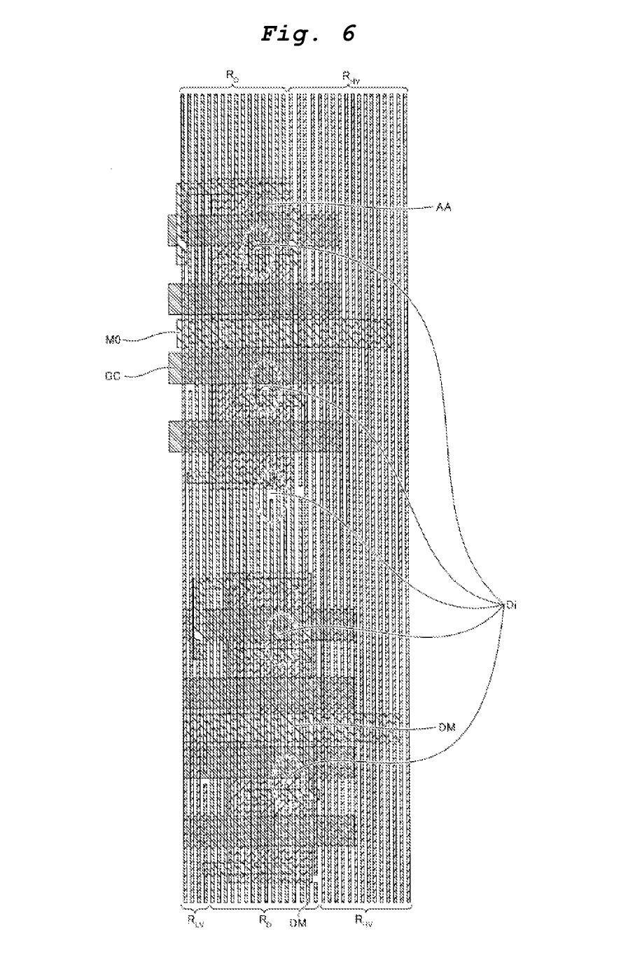

FIG. 4 is a bird's eye view of the BiCS-NAND flash memory of this embodiment. FIG. 5A is a bird's eye view that extracts part of the block (memory cell array) in FIG. 4. FIG. 5B is an equivalent circuit schematic diagram of one of the NAND cell units that are placed in the block.

The storage unit 100 is equipped with a semiconductor substrate 10 and three or more conductive layers that are laminated while being insulated from each other on top of the semiconductor substrate 10; it is also equipped with a string, SP, that is made of multiple semiconductor columns, the bottom end of which is loaded on the semiconductor substrate 10 side, and penetrates the three or more conductive layers. Multiple memory cells MC are installed in each of these strings, SP. It also possesses multiple bit-lines BL, multiple bit-line side select gate line SGD, and a word line, WL. The multiple bit-lines, BL, are positioned on the three or more conductive layers while being insulated from them, and extend in the first direction. Furthermore, the select gate line on the multiple bit-line side, SGD, is made of the conductive layer in the top-most layer of the three or more conductive layers, and extends in the second direction, perpendicular to the first direction. The word line, WL, as the control gate line, is made of the conductive layer that excludes the top-most layer of the three or more conductive layers.

As mentioned above, the peripheral circuit unit 200, which composes the bit-line switch circuit (210 in FIG. 3C), is equipped with multiple read out circuits that are connected to each of the multiple bit-lines, BL, and reads out data to the read out circuit. The read out of data to the read out circuit is done by treating the multiple memory cells that mutually use the select gate line, SGD, on the bit-line side as one unit of the read out.

The storage unit 100 that is made of BiCS-NAND flash memory is composed, for example, of multiple blocks, each of which becomes one unit of erasing. In FIG. 5B, two of the blocks are shown in the diagram.

The other five conductive layers, excluding the top-most layer, are each formed in a plate-shape in one of the blocks. The ends in the x-direction of the other five conductive layers, excluding the top-most layer, are each formed in a step-like fashion in order to make contact with each of the conductive layers. One of the five conductive layers will become the select gate line (second select gate line), SGS, on the source-line side, and the other four conductive layers that exclude the layer which composes this SGS and the top-most layer, will become the word lines, WL.

The top-most layer is composed of multiple line-shaped conductive lines that extend in the x-direction. In one block, for example, six conductive lines are arranged; the six conductive lines in the top-most layer become the select gate lines (first select gate lines), SGD, on the bit-line side.

Multiple active layers (active area), AA, that composes the NAND cell unit are formed in a columnar shape in the z-direction (perpendicular to the surface of the semiconductor substrate), so that they can reach the back gate, BG, after penetrating multiple conductive layers.

The top end of the multiple active layers, AA, are connected to the multiple bit-lines, BL, that extend in the y-direction. Also, the select gate line, SGS, on the source line side is connected to the leader line, SGS·M1, that extends in the x-direction via the contact plug P_{SGS}; the word line, WL, is each connected to the leader line, WL·M1, that extends in the x-direction via the contact plug, P_{WL}.

Furthermore, the select gate lines, SGD, on the bit-line side are each connected to the leader line, SGD·M1, that extends in the x-direction, via the contact plug P_{SGD}.

The multiple bit-lines, BL, and leader lines, SGS−M1, are, for example, composed of metals.

The BiCS-NAND flash memory with a structure shown in FIG. 4 and FIG. 5B, for example, are laminated three or more conductive layers (in this example, it is a six-layered structure) that are composed of conductive polysilicon. The multiple U-shaped active layers (active area), UAA, penetrate the multiple laminated conductive layers, and the memory cell, MC, is formed where the U-shaped active layer, UAA, and the conductive layer that compose the word line, WL, intersect. Regarding the BiCS-NAND flash memory shown in FIG. 4 and FIG. 5B, while, of the laminated conductive layers, the conductive layer of the bottom layer is formed into a plate-shape, the other conductive layers besides the bottom layer are formed into a line-shape. Meanwhile, as shown in FIG. 4, the end of the laminated conductive layer in the x-direction is formed in a step-like fashion in order to make contact with each of the conductive layers.

In the BiCS-NAND flash memory shown in FIG. 4 to FIG. 5B, the multiple active layer UAA, for example seen from the x-direction, has a U-shaped form. As shown in FIG. 5A, the U-shaped active layer, UAA, has a structure where the bottom end of the string, SP, that is made of two semiconductor columns that are formed in a columnar shape, is connected by the joint parts, JP.

Along with this, the source line, SL, is installed on a higher layer than the select gate line on the drain side, SGD, that is installed on the upper end side of the U-shaped active layer, UAA. More specifically, it is installed in a layer between the layer on which the bit-line, BL, is installed and the layer on which the select gate line, SGD, is installed. The source line, SL, extends in the x-direction, and is connected with one of the two semiconductor columns that compose one U-shaped active layer, UAA. And one source line, SL, is shared by two NAND cell unit NANDs that are adjacent to each other in the y-direction.

The select gate line on the source line side, SGS is, for example, composed of the same conductive layer as the select gate line on the bit-line side, SGD, and is a line-shaped conductive line that extends in the x-direction.

In the example shown in FIG. 4 and in FIG. 5B, the word line, WL, is a conductive line that extends in the x-direction.

In a BiCS-NAND flash memory shown in FIG. 4, because one NAND cell unit NAND included string, SP, that is made of two semiconductor columns, as shown in FIG. 5A and FIG. 5B, the number of memory cells that one NAND cell unit possesses becomes large (in this example, it is eight). Meanwhile, in one semiconductor column, SP, there are installed four memory cells, MC.

As shown in FIG. 5A and FIG. 5B, the joint part, JP, can be connected to the back gate BG via the back gate transistor, BGTr. The conductive layer that becomes the back gate, BG, is positioned in a lower layer than the conductive layer that becomes the word line, and the back gate, BG, is, for example, formed so that it forms a plate-shape that spreads two-dimensionally on the semiconductor substrate 10. The back gate transistor, BGTr, is installed in the place where the joint part, JP, and the plate-shaped back gate, BG, intersect, and for example, possesses the same structure as the memory cell, MC. As in this example, in the case of a structure where a back gate is installed, the joint part, JP, for example, is not electronically connected to the semiconductor substrate 10.

Regarding the memory cell structure of the BiCS memory, it is thought that the so-called MONOS type and MNOS type, in which the charge accumulation layer is composed of insulating bodies (for example, nitrides) are effective. However, the example of this invention is not limited to this, and it is possible to apply a floating gate type, in which the charge accumulation layer is composed of conductive polysilicon.

Regarding the data values that can be stored in a memory cell, there can be two stored values or multi-values (multi-level) with three or more values stored as data in a memory cell.

### Embodiment 2

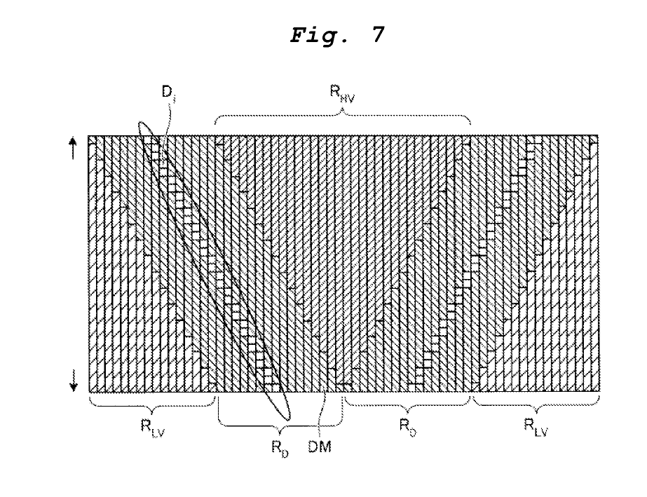

Next, the second embodiment will be described. FIG. 6 is a plan view diagram schematically showing the array of the bit-line wiring part of the three-dimensional laminated-type semiconductor memory that has been applied with the second embodiment of the semiconductor storage device. FIG. 7 is an expanded view of the parts depicted in FIG. 6. Specifically, FIG. 7 has dimensions which have been expanded in the direction of the arrow for sake of explanation, so the depicted dimensional ratio of the length and breadth may be different from reality.

The semiconductor storage device of the second embodiment, on top of the composition of the first embodiment, is characterized by the dummy line, DM, of the dummy wiring part, R_{D}, of the bit-line wiring part in the bit-line switch circuit which is completely divided by the disconnection part Dᵢ. Since the composition of the other parts is the same as that of the semiconductor storage device of the first embodiment, their descriptions are omitted here, but in the same parts, the same reference symbols will be appended where applicable. The composition of the storage unit is also the same as the first embodiment.

According to this composition, because the dummy line, DM, itself is divided by the disconnection part, Dᵢ, it is possible to decrease the total electrical charge that is charged in the dummy line, DM. Also, the disconnection of the dummy line, DM, provides an additional degree of design freedom, and it is possible to use a pattern that is easy to form lithographically. With lithography in mind, the disconnect position of the dummy line, DM, is placed out of alignment.

The dummy line, DM, of the dummy wiring part, R_{D} is extended in the same direction so that it is mutually parallel with the bit-line wiring part, which is composed of the bit-line wiring on the high potential side, BL_{HV} and the bit-line wiring on the low potential side BL_{LV}. It is also disconnected via the disconnection part Dᵢ, and is therefore noncontiguous.

Also in this embodiment, the dummy wiring part, R_{D}, is formed at the same width and at the same spacing as the wiring that composes the bit-line wiring part; however, the dummy wiring part, R_{D}, can be formed in a pattern that possesses a larger spacing than the wiring that composes the bit-line wiring part. With this, it is possible to try to improve the pattern precision.

### Embodiment 3

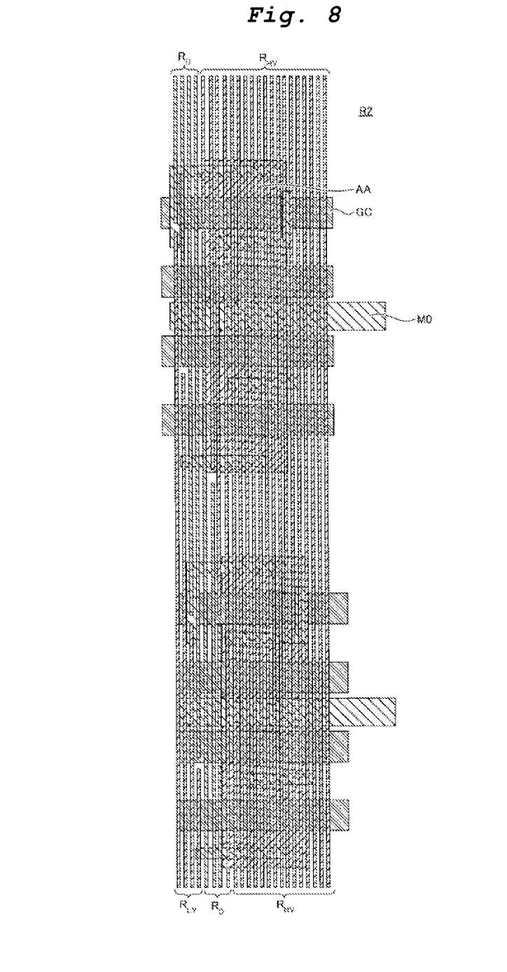

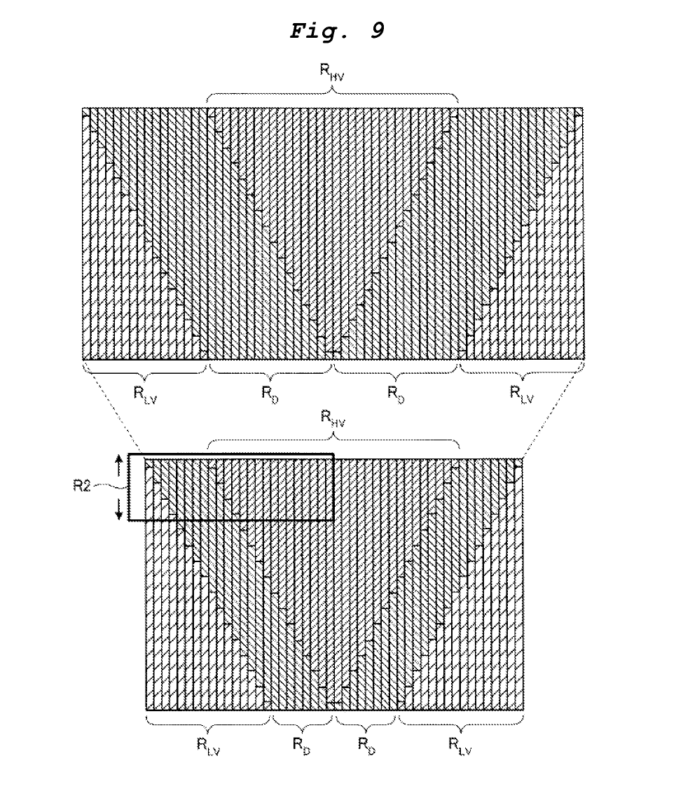

FIG. 8 is a plan view diagram schematically showing the array of the bit-line wiring part R2 of the three-dimensional laminated-type semiconductor memory that has been applied with the third embodiment of the semiconductor storage device. FIG. 9 is a diagram that shows the size comparison example. In this embodiment, the minimum dummy line that is necessary to satisfy the voltage is inserted into the composition of the embodiment 1. This is in order to make a wiring pattern layout with as small of a pitch as possible.

FIG. 9 is a comparative diagram schematically showing the array of the bit-line wiring part of the first embodiment R1, as shown in FIG. 1, and the bit-line wiring part of this embodiment R2. In the first embodiment, 16 dummy lines were inserted, but in this embodiment, based on the requirements of the operating voltage, just 8 were inserted. For example, in the bit-line wiring part R1 of the three-dimensional laminated-type semiconductor memory that has been applied with the first embodiment of the semiconductor storage device, given that the width of the column basic circuit has a width that amounts to twice that of the pair of wiring width/space of the target bit-line, the layout of the first embodiment is sufficient.

In contrast, from the comparison in FIG. 9, in the bit-line wiring part R2 of the three-dimensional laminated-type semiconductor memory that has been applied with the third embodiment of the semiconductor storage device, it is clear that it is effective when the column basic circuit width is short. Also, the number of the dummy line can be decided upon based on the voltage. For example, in the case that the voltage, Vₒ, in a set space of one dummy line is 5 V, when the potential difference, ΔV, between the high potential side wiring part, R_{HV}, and the low potential side wiring part, R_{LV}, is 20 V, ΔV/V₀≦(n+1) from which 3≦n, and so three dummy lines should be installed.

Meanwhile, regarding the composition of the bit-line switch circuit 210, it is not limited to the example of this embodiment, and can be applied in general to bit-line switch circuits of semiconductor storage devices that have a circuit composition in which the high potential side bit-line wiring, BL_{HV}, and the low potential side bit-line wiring, BL_{LV}, are juxtaposed.

While certain embodiments have been described, these embodiments have only been presented as an example, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a storage unit comprising a plurality of memory cells;
a plurality of bit-lines electrically connected to the memory cells;
a voltage generating unit that generates a voltage for erasing data stored in the memory cells;
a sense amplifier that senses the data stored in the memory cells;
a bit-line switch circuit including
a first wiring part which extends in a first direction;
a second wiring part which extends in the first direction and is offset from the first wiring part in a second direction generally perpendicular to the first direction and connects to the sense amplifier;
a third wiring part in an open state which extends in the first direction and is positioned between the first wiring part and the second wiring part in the second direction; and
a switching unit that switches the connection between the bit-lines, the voltage generating unit, and the sense amplifier.

2. The semiconductor storage device of claim 1, wherein the third wiring part comprises a plurality of dummy wires which are segmented in the first direction into electrically isolated portions by a disconnection part.

3. The semiconductor storage device of claim 2, wherein the third wiring part is arranged diagonally between the first and second wiring part.

4. The semiconductor storage device of claim 1, wherein the third wiring part comprises a number of wires and the number is set according to the voltage generated by the voltage generating circuit.

5. The semiconductor storage device of claim 4, wherein the third wiring part is comprised of wires each with the same width as wires in the first or second wiring part.

6. The semiconductor storage device of claim 1, wherein the third wiring part is comprised of wires each with the same width as wires in the first or second wiring part.

7. The semiconductor storage device of claim 1, wherein the memory cells are laminated on a semiconductor substrate.

8. The semiconductor storage device of claim 1, wherein each memory cell can store three or more data values.

9. The semiconductor storage device of claim 1, wherein the plurality of memory cells store charges in an accumulation layer composed of insulating bodies.

10. The semiconductor storage device of claim 9, wherein the accumulation layer comprises a nitride insulation layer.

11. The semiconductor storage device of claim 1, wherein the plurality of memory cells store charges in an accumulation layer composed of conductive polysilicon.

12. A semiconductor storage device comprising:
a storage unit that includes a plurality of memory cells;
a plurality of bit-lines that are electrically connected to the memory cells;
a voltage generating unit that generates a voltage for erasing data in the memory cells;
a sense amplifier that senses the data on the memory cells; and
a bit-line switch circuit including
a first wiring part which extends in a first direction;
a second wiring part which is offset from the first wiring part in a second direction that intersects with the first direction;
a third wiring part in an open state that is positioned between the first wiring part and the second wiring part in the second direction; and
a switching unit that switches the connection between the bit-lines, the voltage generating unit, and the sense amplifier,
wherein the third wiring part comprises a plurality of dummy wires which are segmented in the first direction into electrically isolated portions by a disconnection part.

13. The semiconductor storage device according to claim 12, wherein
the first and second wiring parts are divided by a divider part that is formed diagonally relative to the first direction so that the end parts of both the first and second wiring parts are parallel in the second direction; and
the divider part is disposed within third wiring part.

14. The semiconductor storage device according to claim 13, wherein
the third wiring part extends in the first direction and is segmented in the first direction by a disconnection part.

15. The semiconductor storage device according to claim 12, wherein the third wiring part comprises a number of wires and the number is determined according to the voltage generated by the voltage generating circuit.

16. The semiconductor storage device according to claim 13, wherein the third wiring part comprises a number of wires and the number is determined according to the voltage generated by the voltage generating circuit.

17. The semiconductor storage device according to claim 14, wherein the third wiring part comprises a number of wires and the number is determined according to the voltage generated by the voltage generating circuit.

18. A semiconductor storage device, comprising
a plurality of bit lines, each bit line connected to a plurality of memory cells arranged in a laminated array;
a bit-line switch circuit including
a first wiring part comprising a plurality of wires electrically connected to a high potential side;
a second wiring part comprising a plurality of wires electrically connected to a low potential side;
a third wiring part comprising a plurality of wires of floating potential; and
a switching unit that switches the connection between the bit-lines, the voltage generating unit, and the sense amplifier,
wherein
the wires of the first, second, and third wiring parts generally share a common plane and extend in a first direction;
the wires of the first and second wiring parts are arranged such that they are offset from each other in a second direction perpendicular to the first direction;
the ends of the wires of the first and second wiring parts are in a staggered arrangement, such that ends of wires in the first and second wiring parts are separated in the second direction by a same number of wires of the third wiring part.

19. The storage device of claim 18, wherein the wires of the third wiring part have the same size and spacing as the wires of the first or second wiring part.

20. The storage device of claim 18, wherein the third wiring part further comprises a disconnection part.
